(19) United States
(12) Patent Application Publication
(10) Pub. No.: US 2008/0078991 A1
(43) Pub. Date: Apr. 3, 2008

(54) ORGANIC LIGHT EMITTING DISPLAY AND FABRICATING METHOD THEREOF AND MOVING DEVICE THEREFOR

(76) Inventor: Jongyun Kim, Yongin-si (KR)

Correspondence Address: CHRISTIE, PARKER & HALE, LLP, PO BOX 7068, PASADENA, CA, 91109-7068, US

(21) Appl. No.: 11/735,373

(22) Filed: Apr. 13, 2007

(30) Foreign Application Priority Data
Sep. 28, 2006 (KR) 10-2006-0095134

(51) Int. Cl. H01L 29/06; H01L 21/02

(52) U.S. Cl. 257/40; 438/29

(57) ABSTRACT

An organic light emitting display includes: a substrate; a buffer layer disposed on a top surface of the substrate; a semiconductor layer disposed on the buffer layer; a gate insulating layer disposed on the semiconductor layer; a gate electrode disposed on the gate insulating layer; an inter-layer dielectric layer disposed on the gate electrode; a source/drain electrode disposed on the inter-layer dielectric layer; an insulating layer disposed on the source/drain electrode; an organic light emitting diode disposed on the insulating layer; and a non-transmissive layer disposed on a bottom surface of the substrate.

### CROSS-REFERENCE TO RELATED APPLICATION

This application claims priority to and the benefit of Korean Patent Application No. 10-2006-95134, filed on Sep. 28, 2006, in the Korean Intellectual Property Office, the entire content of which is incorporated herein by reference.

### BACKGROUND

1. Field of the Invention

The present invention relates to an organic light emitting display, a fabricating method thereof and a moving device therefor, and, more particularly, to a thin organic light emitting display, a fabricating method thereof and a moving device therefor that can manufacture the thin organic light emitting display.

2. Description of the Related Art

An organic light emitting display can be a flat panel display device that can self-emit lights through application of an electric current to a fluorescent or phosphorescent organic compound and recombination of electrons and holes. The organic light emitting display can display an image by driving organic light emitting diodes, for example organic light emitting diodes of an n by m matrix, by a voltage or a current.

As shown in FIG. 1, an organic light emitting diode has an anode (ITO), an organic thin layer and a cathode electrode (metal). The organic thin layer can include: an emitting layer (EML) that emits light by coupling electrons and holes and forming excitons; an electron transport layer (ETL) that properly controls the moving velocity of the electrons; and a hole transport layer (HTL) that properly controls the moving velocity of the holes. An electron injecting layer (EIL) for improving the electron injection efficiency can be further formed on the electron transport layer, and a hole injecting layer (HIL) for improving the hole injection efficiency can be further formed on the hole transport layer.

The organic light emitting display can be applied to wide varieties of moving image flat panel display devices because of its wide viewing angle, high response speed, ability to self-emit light and so forth. Moreover, the organic light emitting display has low power consumption and can be manufactured to be lightweight and thin because a backlight is not needed. Furthermore, the organic light emitting display can be manufactured at a low temperature and can be manufactured at a low cost because of its simple fabricating process.

In addition, as electronic devices, such as a cellular phone, a Personal Digital Assistant (PDA), a notebook, a computer monitor, a television and so forth, become slimmer, a flat panel display device (e.g., an organic light emitting display) should also be manufactured to be thinner (or slimmer), e.g., having a thickness of below about 1 mm. However, in a typical organic light emitting display, it is difficult to manufacture the organic light emitting display having a thickness of below 1 mm due to a need to protect and/or encapsulate the element layers of the organic light emitting display (e.g., the semiconductor layer, the organic light emitting diode, etc.).

### SUMMARY OF THE INVENTION

An aspect of the present invention is to provide a thin organic light emitting display, a fabricating method thereof and a moving device therefor.

Another aspect of the present invention is to improve the productivity and reduce the fabricating cost by reducing the fabricating process time.

Another aspect of the present invention is to block (or prevent) a warping phenomenon of a substrate during a fabrication process and to block (or prevent) a damage and breakage phenomenon of the substrate by blocking (or preventing) a physical contact of the center of the substrate.

An organic light emitting display according to an embodiment of the present invention includes: a substrate having a first surface and a second surface; an organic light emitting diode, an insulating layer and a semiconductor layer disposed on the first surface of the substrate, the insulating layer being disposed between the organic light emitting diode and the semiconductor layer; and a non-transmissive layer disposed on the second surface of the substrate. Here, the non-transmissive layer is adapted to block a UV-ray.

In one embodiment, the organic light emitting display further includes: a buffer layer disposed on the first surface of the substrate, the semiconductor layer being disposed on the buffer layer; a gate insulating layer disposed on the semiconductor layer; a gate electrode disposed on the gate insulating layer; an inter-layer dielectric layer disposed on the gate electrode; and a source/drain electrode disposed on the inter-layer dielectric layer, the insulating layer being disposed on the source/drain electrode and the organic light emitting diode being disposed on the insulating layer.

In another embodiment, the organic light emitting display further includes: a buffer layer disposed on the first surface of the substrate, the gate electrode being disposed on the buffer layer; a gate insulating layer disposed on the gate electrode; a semiconductor layer disposed on the gate insulating layer; an inter-layer dielectric layer disposed on the semiconductor layer; and a source/drain electrode disposed on the inter-layer dielectric layer, the insulating layer being disposed on the source/drain electrode and the organic light emitting diode being disposed on the insulating layer.

The thickness of the substrate can be from about 0.05 mm to about 1 mm.

The substrate can include a material selected from glass, plastic, polymer, steel, and combinations thereof.

The thickness of the non-transmissive layer can be from about 500 Å to about 3000 Å.

The non-transmissive layer can include a UV-ray protective agent.

The non-transmissive layer can include a material selected from a metal that does not transmit the UV-ray, a transparent UV-ray protective agent, an opaque UV-ray protective agent, and combinations thereof.

The non-transmissive layer can include a material selected from chrome (Cr), chrome oxide (Cr₂O₃), aluminum (Al), gold (Au), silver (Ag), magnesium oxide (MgO), silver alloy, and combination thereof.

A magnetic layer can be further disposed on the bottom surface of the non-transmissive layer.

The thickness of the magnetic layer can be from about 10 μm to about 100 μm.

An anti-friction layer can be further disposed on the bottom surface of the magnetic layer.

An anti-friction layer can be further disposed on the bottom surface of the non-transmissive layer.

The thickness of the anti-friction layer can be from about 10 μm to about 100 μm.

The anti-friction layer can include a material selected from an organic material and an inorganic material.

An encapsulant can be disposed on the circumference of the first surface of the substrate, and an encapsulation substrate is attached to the encapsulant.

A fabricating method of an organic light emitting display according to an embodiment of the present invention includes: providing a first substrate and a second substrate; forming a first non-transmissive layer on a bottom surface of the first substrate; forming a second non-transmissive layer on a bottom surface of the second substrate; bonding the first substrate with the second substrate so that the first and second non-transmissive layers face each other; forming a first semiconductor layer on a top surface of the first bonded substrate; forming a second semiconductor layer on a top surface of the second bonded substrate; forming a first organic light emitting diode on the first semiconductor layer; forming a second organic light emitting diode on the second semiconductor layer; attaching an encapsulation substrate by an encapsulant to a surface on which each organic light emitting diode is formed; cutting an edge portion of the first and second substrates on which the first and second semiconductor layers and the first and second organic light emitting diodes are not formed; and separating the first and second bonded substrates into a first fabricated substrate and a second fabricated substrate.

At least one of the first substrate or the second substrate can have a thickness ranging from about 0.05 mm to about 1 mm.

At least one of the first substrate or the second substrate can include a material selected from the group consisting of glass, plastic, polymer, steel, and combinations thereof.

At least one of the first non-transmissive layer or the second non-transmissive layer can be formed to have a thickness ranging from about 500 Å to about 3000 Å.

At least one of the first non-transmissive layer or the second non-transmissive layer can be formed by coating a UV-ray protective agent on the bottom surface of at least one of the first substrate or the second substrate.

At least one of the first non-transmissive layer or the second non-transmissive layer can be formed by forming a material selected from the group consisting of a metal that does not transmit the UV-ray, a transparent UV-ray protective agent, an opaque UV-ray protective agent, and combinations thereof on the bottom surface of at least one of the first substrate or the second substrate.

At least one of the first non-transmissive layer or the second non-transmissive layer can be formed by forming a material selected from the group consisting of chrome (Cr), chrome oxide (Cr₂O₃), aluminum (Al), gold (Au), silver (Ag), magnesium oxide (MgO), silver alloy, and combinations thereof on the bottom surface of at least one of the first substrate or the second substrate.

The forming of at least one of the first non-transmissive layer or the second non-transmissive layer can be performed by further forming a magnetic layer on a bottom surface of at least one of the first non-transmissive layer or the second non-transmissive layer.

The forming of at least one of the first non-transmissive layer or the second non-transmissive layer can be performed by further forming an anti-friction layer on a bottom surface of the magnetic layer.

The forming of at least one of the first non-transmissive layer or the second non-transmissive layer can be performed by further forming a magnetic layer having a thickness ranging from 10 μm to 100 μm on a bottom surface of at least of one the first non-transmissive layer or the second non-transmissive layer.

The forming of at least one of the first non-transmissive layer or the second non-transmissive layer can be performed by further forming an anti-friction layer on the bottom surface of at least one of the first substrate or the second substrate.

The forming of at least one of the first non-transmissive layer or the second non-transmissive layer can be performed by further forming an anti-friction layer having a thickness ranging from 10 μm to 100 μm on a bottom surface of at least one of the first substrate or the second substrate.

The forming of at least one of the first non-transmissive layer or the second non-transmissive layer can be performed by further forming an anti-friction layer including a material selected from the group consisting of an organic material and an inorganic material on a bottom surface of at least one of the first non-transmissive layer or the second non-transmissive layer.

In the bonding of the first and second substrates, the first and second substrates can be bonded to each other by interposing a bonding agent between the first and second substrates.

The bonding of the first and second substrates can be performed by using an epoxy adhesive as the bonding agent.

The bonding of the first and second substrates can performed by forming the bonding agent on an edge portion of at least one of the first substrate or the second substrate.

The bonding of the first and second substrates can performed by forming the bonding agent on an inner circumference of at least one of the first substrate or the second substrate in the form of a plurality of lines.

The forming of the anti-friction layer on the bottom surface of at least one of the first substrate or the second substrate can include forming a first anti-friction layer on the bottom surface of the first substrate and a second anti-friction layer on the bottom surface of the second substrate, and the bonding of the first and second substrates can be performed by contacting the first and second anti-friction layers formed on the first and second substrates with each other.

The encapsulation substrate used in the attaching of the encapsulation substrate can have an area smaller than that of at least one of the first substrate or the second substrate.

At least two opposite edges of the encapsulation substrate used in the attaching of the encapsulation substrate can be shorter by 3 cm to 8 cm in an inward direction of that of at least one of the first substrate or the second substrate.

The cutting can be performed by cutting at least one of the first substrate or the second substrate and the encapsulation substrate at a position corresponding to an outer circumference of at least one of the first semiconductor layer or the second semiconductor layer and at least one of the first organic light emitting diode or the second organic light emitting diode.

The cutting can be performed by a laser beam.

The cutting can be performed by removing the bonding agent from at least one of the first substrate or the second substrate.

The fabricating method can further include removing the anti-friction layer, the magnetic layer and/or at least one of the first non-transmissive layer or the second non-transmissive layer after the separating of the first and second substrates.

The fabricating method can further include removing at least one of the first non-transmissive layer or the second non-transmissive layer after the separating of the first and second substrates.

The fabricating method can further include injecting a liquid anti-friction layer between the first and second substrates after the bonding of the first and second substrates to each other.

A moving device for an organic light emitting display according to an embodiment of the present invention includes: a moving body having an opening formed on one side thereof, in which a step having a depth is disposed on a circumference of the opening so as to receive the organic light emitting display formed by two bonded substrates; and at least one shock-absorbing member extending from the step of the moving body by a distance and adapted to absorb a shock and to block the bonded organic light emitting display from warping.

The moving device can further include an anti-slide pad disposed on the step of the moving body and adapted to receive the bonded organic light emitting display and to block the bonded organic light emitting display from sliding.

The anti-slide pad can include a material selected from the group consisting of rubber, silicon, and combinations thereof.

The moving device can further include a magnet attached to a region of the shock-absorbing member facing the bonded organic light emitting display.

The moving device can further include an elastic part disposed on a coupling region of the shock-absorbing member with the moving body.

The elastic part can be a part selected from the group consisting of a spring, an air cylinder, a shock-absorbing pad, and combinations thereof.

As such, the organic light emitting display according to one embodiment can be readily applied to various electronic display devices, such as a cellular phone, a PDA, a notebook, a computer monitor and a television that are thin (or slim), by forming the organic light emitting display on a substrate having a thickness of from 0.05 mm to 1 mm.

Moreover, in one embodiment, the organic light emitting display can block (or prevent) a UV-ray from affecting a semiconductor layer and/or an organic light emitting diode through the substrate during use by forming a non-transmissive layer on the substrate.

The fabricating method of an organic light emitting display according to one embodiment can reduce an entire processing time by about 50% by bonding two substrates having (or each having) the thickness of from 0.05 mm to 1 mm and performing simultaneously (or concurrently) a semiconductor forming process and an organic thin layer forming process (in one embodiment, each process includes a cleaning operation, an etching operation, a light exposure operation, a development operation, a heat treatment operation and so on).

Moreover, the fabricating method can block (or prevent) a UV-ray due to a light exposure operation during a fabricating process from affecting another opposing organic light emitting display by forming the non-transmissive layer on the bottom surface of the substrate.

Furthermore, the fabricating method can block (or prevent) the organic light emitting display from warping or being damaged due to gravity by the repulsive force between the magnetic layer and the moving device moving the magnetic layer during a fabricating process by forming the non-transmissive layer and the magnetic layer on the bottom surface of the substrate.

In addition, the fabricating method can block (or prevent) the substrates or the metals formed on the surfaces of the substrates from contacting with each other when bonding the two substrates and thus can block (or prevent) the damage of the substrate by forming the non-transmissive layer, the magnetic layer and the anti-friction layer or the non-transmissive layer and the anti-friction layer on the bottom surface of the substrate.

The moving device of the organic light emitting display according to one embodiment can block or prevent the substrate from warping or being damaged, by supporting the edge portion of the substrate on which a semiconductor layer and/or an organic light emitting diode are not formed by an anti-slide pad having a relatively high elasticity, and by supporting the central region of the substrate on which the semiconductor layer and/or the organic light emitting diode are formed by a shock-absorbing member in a non-contact manner.

Moreover, the moving device can block or prevent the central region of the substrate, which is not supported by the anti-slide pad, from contacting with the shock-absorbing member and can maintain the flat state of the central region of the substrate during transfer or process, by mounting the magnet on the shock-absorbing member so as to repulse the magnetic layer formed on the two bonded substrates.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a schematic view showing an organic light emitting diode.

FIGS. 2a, 2b, 2c, 2d, and 2e are sectional schematic views showing organic light emitting displays according to embodiments of the present invention.

FIGS. 3a, 3b, 3c, 3d, and 3e are sectional schematic views showing organic light emitting displays according to embodiments of the present invention with an encapsulation operation completed.

FIG. 4 is a flow chart showing a fabricating method of an organic light emitting display according to an embodiment of the present invention.

FIGS. 5a, 5b, 5c, 5d, 5e, 5f, 5g, 5h, and 5i are sectional schematic views showing a fabricating sequence of an organic light emitting display according to an embodiment of the present invention.

FIGS. 6a and 6b are top schematic views showing a moving device of an organic light emitting display according to an embodiment of the present invention, and FIG. 6c is a sectional view taken along a line A-A of FIG. 6b.

FIG. 7 is an enlarged partial sectional schematic view showing a state in which a bonded substrate is supported by a shock absorber in a moving device.

FIG. 8 is a sectional schematic view showing a part of an organic light emitting display according to an embodiment of the present invention.

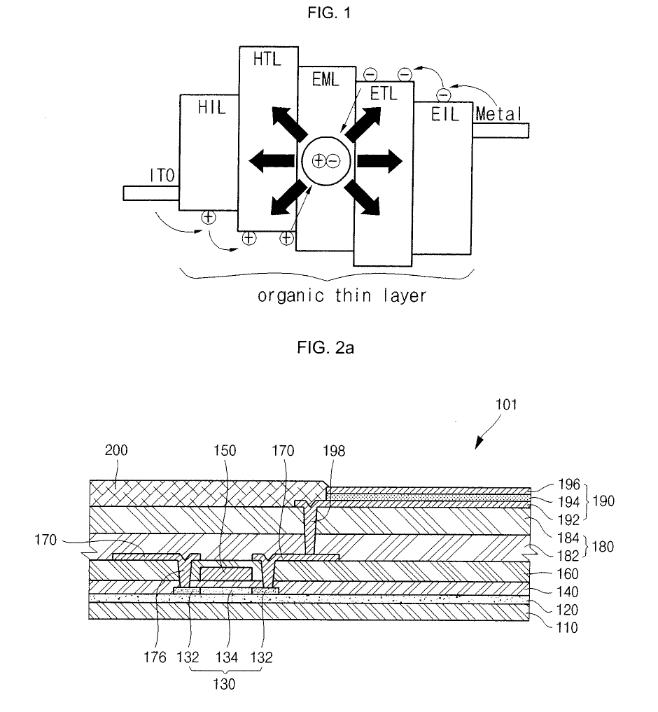

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when an element is referred to as being “on” another element, it can be directly on the another element or be indirectly on the another element with one or more intervening elements interposed therebetween. Like reference numerals designate like elements throughout the specification.

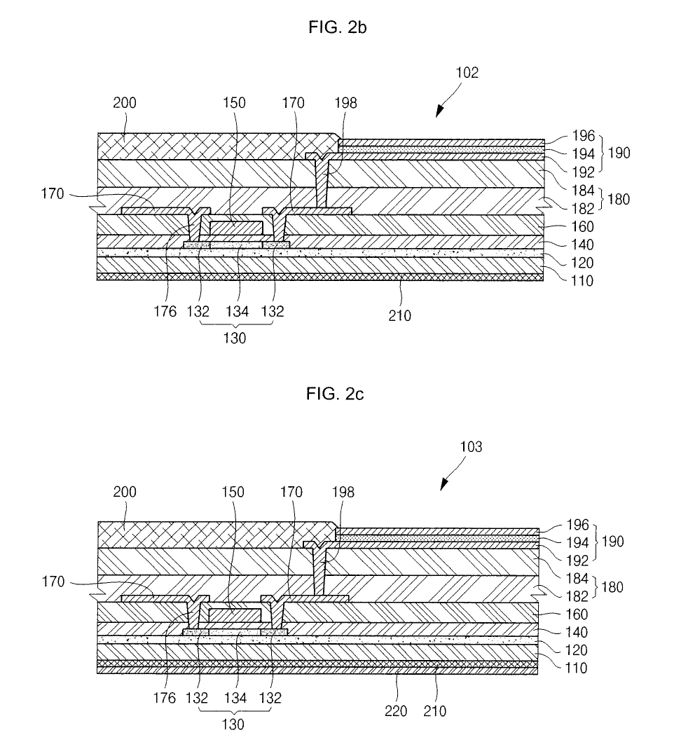

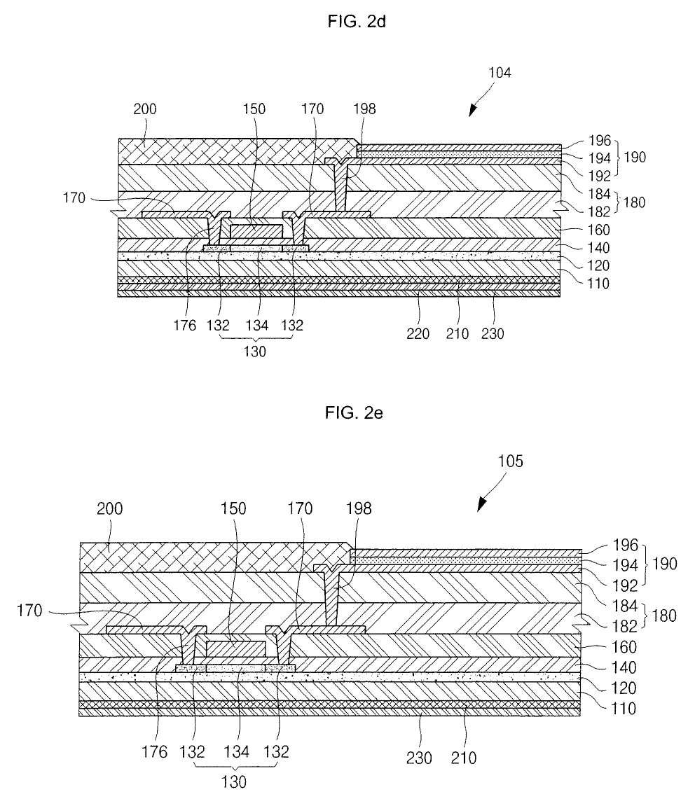

FIGS. 2a to 2e are sectional schematic views showing organic light emitting displays 101, 102 103, 104 and 105 according to embodiments of the present invention.

As shown in FIG. 2a, the organic light emitting display 101 includes: a substrate 110; a buffer layer 120 formed on the substrate 110; a semiconductor layer 130 formed on the buffer layer 120; a gate insulating layer 140 formed on the semiconductor layer 130; a gate electrode 150 formed on the gate insulating layer 140; an inter-layer dielectric layer 160 formed on the gate electrode 150; a source/drain electrode 170 formed on the inter-layer dielectric layer 160; an insulating layer 180 formed on the source/drain electrode 170; an organic light emitting diode 190 formed on the insulating layer 180; and a pixel defining layer 200 formed on the insulating layer 180 at the outer circumference of the organic light emitting diode 190.

The top and bottom surfaces of the substrate 110 are substantially flat, and the thickness between the top surface and the bottom (under) surface can be from about 0.05 mm to about 1 mm. In one embodiment, if the thickness of the substrate 110 is below about 0.05 mm, the substrate 110 may be damaged due to cleaning, etching and heat treatment processes and has a low strength against an external force. In another embodiment, if the thickness of the substrate 110 is above about 1 mm, it is difficult to apply the substrate to various display devices that are to be thin (or slim). Furthermore, the substrate 110 can be formed of any material selected from glass, plastic, polymer, steel and their equivalents, but not limited thereto.

The buffer layer 120 can be formed on the top surface of the substrate 110. The buffer layer 120 is for reducing (or preventing) moisture (H₂O), hydrogen (H₂) or oxygen (O₂), etc. from penetrating through the substrate 110 and infiltrating into the semiconductor layer 130 or the organic light emitting diode 190. For this purpose, the buffer layer 120 can be formed of any layer selected from an oxide layer (SiO₂), a nitride layer (Si₃N₄) and their equivalents that can be easily formed during a semiconductor process, but not limited thereto. In one embodiment, the buffer layer 120 can be omitted.

The semiconductor layer 130 can be formed on the top surface of the buffer layer 120. The semiconductor layer 130 can include source/drain sections 132 formed at two opposite sides of the semiconductor layer 130 and a channel section 134 formed between the source/drain sections 132. In one embodiment, the semiconductor layer 130 may be part of a thin film transistor. The thin film transistor can be formed of any transistor selected from an amorphous silicone thin film transistor, a poly-silicone thin film transistor, an organic thin film transistor, a micro silicone thin film transistor and their equivalents, but not limited thereto. Moreover, in case of the poly-silicone thin film transistor, the poly-silicone thin film transistor can be crystallized by a crystallizing method using a laser at a low temperature, a crystallizing method using a metal, a crystallizing method using a high pressure and their equivalents, but not limited thereto. The crystallizing method using a laser may include an Excimer Laser Annealing (ELA) method, a Sequential Lateral Solidification (SLS) method, a Thin Beam Direction Crystallization (TDX) method, etc., but not limited thereto. Moreover, the crystallizing method using a metal may include a Solid Phase Crystallization (SLS) method, a Metal Induced Crystallization (MIC) method, a Metal Induced Lateral Crystallization (MILC) method, and a Super Grained Silicone (SGS) method, but not limited thereto. In one embodiment, the thin film transistor may be any MOS selected from a PMOS, an NMOS and their equivalents, but not limited thereto.

The gate insulating layer 140 can be formed on the top surface of the semiconductor layer 130. In one embodiment, the gate insulating layer 140 can also be formed on the buffer layer 120 at the outer circumference of the semiconductor layer 130. Moreover, the gate insulating layer 140 can be formed of any layer selected from an oxide layer, a nitride layer and their equivalents that can be easily formed during a semiconductor process, but not limited thereto.

The gate electrode 150 can be formed on the top surface of the gate insulating layer 140. More specifically, the gate electrode 150 can be formed on the gate insulating layer 140 to correspond to the channel section 134 of the semiconductor layer 130. The gate electrode 150 enables a hole or electron channel to be formed in the channel section 134 by applying an electric field to the channel section 134 in the lower part of the gate insulating layer 140. Moreover, the gate electrode 150 can be formed of any material selected from metal (e.g., MoW, Ti, Cu, AlNd, Al, Cr, Mo alloy, Cu alloy, Al alloy, etc.), doped poly silicone and their equivalents, but not limited thereto.

The inter-layer dielectric layer 160 can be formed on the top surface of the gate electrode 150. In one embodiment, the inter-layer dielectric layer 160 can also be formed on the gate insulating layer 140 at the outer circumference of the gate electrode 150. Moreover, the inter-layer dielectric layer 160 can be formed of any material selected from a polymer-based insulating material, a plastic-based insulating material, a glass-based insulating material and their equivalents, but not limited thereto.

The source/drain electrode 170 can be formed on the top surface of the inter-layer dielectric layer 160. In one embodiment, an electrically conductive contact 176 penetrating through the inter-layer dielectric layer 160 can be formed between the semiconductor layer 130 and the source/drain electrode 170. That is, the semiconductor layer 130 is electrically coupled with the source/drain electrode 170 via (or by) the electrically conductive contact 176. Moreover, the source/drain electrode 170 can be formed of a metal material that is substantially the same as that of the gate electrode 150, but not limited thereto. Also, the semiconductor layer 130 (i.e., thin film transistor) can have an ordinary coplanar structure. However, the semiconductor layer 130 described in the present invention is not limited to the coplanar structure. The semiconductor layer can have any suitable structure for a thin film transistor, for example, any structure selected from an inverted coplanar structure, a staggered structure, an inverted staggered structure and their equivalents, but not limited thereto.

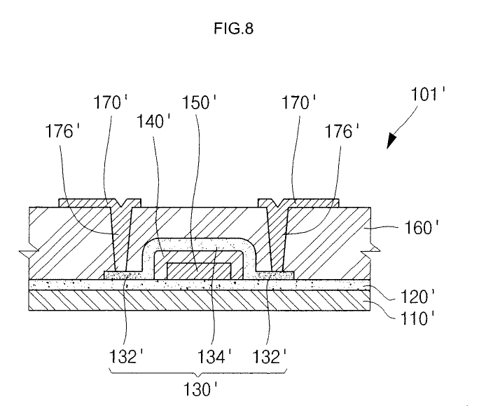

As an example, an inverted coplanar structure according to an embodiment of the present invention is shown in FIG. 8. In FIG. 8, an organic light emitting display 101′ includes: a substrate 110′; a buffer layer 120′ formed on the substrate 110′; a gate electrode 150′ formed on the buffer layer 120′; a gate insulating layer 140′ formed on the gate electrode 150′; a semiconductor layer 130′ formed on the gate insulating layer 140′; an inter-layer dielectric layer 160′ formed on the semiconductor layer 130′; and a source/drain electrode 170′ formed on the inter-layer dielectric layer 160′; an insulating layer (e.g., layer 180) formed on the source/drain electrode 170′; an organic light emitting diode (e.g., diode 190) formed on the insulating layer; and a pixel defining layer (e.g., layer 200) formed on the insulating layer at the outer circumference of the organic light emitting diode. The semiconductor layer 130′ can include source/drain sections 132′ formed at two opposite sides of the semiconductor layer 130′ and a channel section 134′ formed between the source/drain sections 132′. In one embodiment, the semiconductor layer 130′ may be part of a thin film transistor. In one embodiment, an electrically conductive contact 176′ penetrating through the inter-layer dielectric layer 160′ can be formed between the semiconductor layer 130′ and the source/drain electrode 170′. That is, the semiconductor layer 130′ is electrically coupled with the source/drain electrode 170′ via (or by) the electrically conductive contact 176′.

Referring back to FIG. 2a, the top and bottom surfaces of the substrate 110 according to one embodiment are substantially flat, and the thickness between the top surface and the bottom (under) surface can be from about 0.05 mm to about 1 mm. In one embodiment, if the thickness of the substrate 110 is below about 0.05 mm, the substrate 110 may be damaged due to cleaning, etching and heat treatment processes and has a low strength against an external force. In another embodiment, if the thickness of the substrate 110 is above about 1 mm, it is difficult to apply the substrate to various display devices that are to be thin (or slim). Furthermore, the substrate 110 can be formed of any material selected from glass, plastic, polymer, steel and their equivalents, but not limited thereto.

The buffer layer 120 can be formed on the top surface of the substrate 110. The buffer layer 120 is for reducing (or preventing) moisture (H₂O), hydrogen (H₂) or oxygen (O₂), etc. from penetrating through the substrate 110 and infiltrating into the semiconductor layer 130 or the organic light emitting diode 190. For this purpose, the buffer layer 120 can be formed of any layer selected from an oxide layer (SiO₂), a nitride layer (Si₃N₄) and their equivalents that can be easily formed during a semiconductor process, but not limited thereto. In one embodiment, the buffer layer 120 can be omitted.

The semiconductor layer 130 can be formed on the top surface of the buffer layer 120. The semiconductor layer 130 can include source/drain sections 132 formed at two opposite sides of the semiconductor layer 130 and a channel section 134 formed between the source/drain sections 132. In one embodiment, the semiconductor layer 130 may be part of a thin film transistor. The thin film transistor can be formed of any transistor selected from an amorphous silicone thin film transistor, a poly-silicone thin film transistor, an organic thin film transistor, a micro silicone thin film transistor and their equivalents, but not limited thereto. Moreover, in case of the poly-silicone thin film transistor, the poly-silicone thin film transistor can be crystallized by a crystallizing method using a laser at a low temperature, a crystallizing method using a metal, a crystallizing method using a high pressure and their equivalents, but not limited thereto. The crystallizing method using a laser may include an Excimer Laser Annealing (ELA) method, a Sequential Lateral Solidification (SLS) method, a Thin Beam Direction Crystallization (TDX) method, etc., but not limited thereto. Moreover, the crystallizing method using a metal may include a Solid Phase Crystallization (SLS) method, a Metal Induced Crystallization (MIC) method, a Metal Induced Lateral Crystallization (MILC) method, and a Super Grained Silicone (SGS) method, but not limited thereto. In one embodiment, the thin film transistor may be any MOS selected from a PMOS, an NMOS and their equivalents, but not limited thereto.

The gate insulating layer 140 can be formed on the top surface of the semiconductor layer 130. In one embodiment, the gate insulating layer 140 can also be formed on the buffer layer 120 at the outer circumference of the semiconductor layer 130. Moreover, the gate insulating layer 140 can be formed of any layer selected from an oxide layer, a nitride layer and their equivalents that can be easily formed during a semiconductor process, but not limited thereto.

The gate electrode 150 can be formed on the top surface of the gate insulating layer 140. More specifically, the gate electrode 150 can be formed on the gate insulating layer 140 to correspond to the channel section 134 of the semiconductor layer 130. The gate electrode 150 enables a hole or electron channel to be formed in the channel section 134 by applying an electric field to the channel section 134 in the lower part of the gate insulating layer 140. Moreover, the gate electrode 150 can be formed of any material selected from metal (e.g., MoW, Ti, Cu, AlNd, Al, Cr, Mo alloy, Cu alloy, Al alloy, etc.), doped poly silicone and their equivalents, but not limited thereto.

The inter-layer dielectric layer 160 can be formed on the top surface of the gate electrode 150. In one embodiment, the inter-layer dielectric layer 160 can also be formed on the gate insulating layer 140 at the outer circumference of the gate electrode 150. Moreover, the inter-layer dielectric layer 160 can be formed of any material selected from a polymer-based insulating material, a plastic-based insulating material, a glass-based insulating material and their equivalents, but not limited thereto.

The source/drain electrode 170 can be formed on the top surface of the inter-layer dielectric layer 160. In one embodiment, an electrically conductive contact 176 penetrating through the inter-layer dielectric layer 160 can be formed between the semiconductor layer 130 and the source/drain electrode 170. That is, the semiconductor layer 130 is electrically coupled with the source/drain electrode 170 via (or by) the electrically conductive contact 176. Moreover, the source/drain electrode 170 can be formed of a metal material that is substantially the same as that of the gate electrode 150, but not limited thereto. Also, the semiconductor layer 130 (i.e., thin film transistor) can have an ordinary coplanar structure. However, the semiconductor layer 130 described in the present invention is not limited to the coplanar structure. The semiconductor layer can have any suitable structure for a thin film transistor, for example, any structure selected from an inverted coplanar structure, a staggered structure, an inverted staggered structure and their equivalents, but not limited thereto.

The insulating layer 180 can be formed on the top surface of the source/drain electrode 170. The insulating layer 180 can include a protective layer 182 and a planarization layer 184 formed on the top surface of the protective layer 182. The protective layer 182 is for covering the source/drain electrode 170 and the inter-layer dielectric layer 160 and for protecting the source/drain electrode 170 and the gate electrode 150, etc. The protective layer 182 can be formed of any layer selected from an inorganic layer and its equivalent, but not limited thereto. The planarization layer 184 covers the protective layer 182. The planarization layer 184 is for flattening the entire (or substantially the entire) surface of the protective layer 182 (or the device above and/or below the planarization layer 184) and can be formed of any material selected from Benzo Cyclo Butene (BCB), acryl and their equivalents, but not limited thereto.

The organic light emitting diode 190 can be formed on the top surface of the insulating layer 180. The organic light emitting diode 190 can include an anode 192, an organic light emitting thin layer 194 formed on the top surface of the anode 192 and a cathode 196 formed on the top surface of the organic light emitting thin layer 194. The anode 192 can be formed of any material selected from Indium Tin Oxide (ITO), ITO/Ag, ITO/Ag/ITO and their equivalents, but not limited thereto. The ITO is a transparent conductive material (or layer) in which a work function is uniform and a hole injecting barrier to the organic light emitting thin layer 194 is small, and the Ag is a layer that reflects the light emitted from the organic light emitting thin layer 194 to the top surface of the display 101 in a top emission system. In addition, the organic light emitting thin layer 194 can include an emitting layer (EML) that emits the light by joining the electrons with the holes and forming excitons, an electron transport layer (ETL) that adequately adjusts the moving velocity of the electrons, and a hole transport layer (HTL) that adequately adjusts the moving velocity of the holes. Moreover, an electron injecting layer (EIL) for improving the injection efficiency of the electron can be formed on the electron transport layer, and a hole injecting layer (HIL) for improving the injection efficiency of the hole can be further formed on the hole transport layer. Furthermore, the cathode 196 can be formed of any material selected from Al, MgAg alloy, MgCa alloy and their equivalents, but not limited thereto. If the top emission system is employed and the cathode is formed of Al, then the thickness of the cathode (or the Al cathode) should be sufficiently thin. However, in this case, the resistance of the Al cathode may be relatively high, and thus the electron injecting barrier may become relatively large. The MgAg alloy has an electron injecting barrier that is smaller than that of the Al, and the MgCa alloy has an electron injecting barrier that is smaller than that of the MgAg Alloy. However, the MgAg alloy and the MgCa alloy should be completely protected (encapsulated or blocked) from the outside because they are sensitive to the surrounding environment and can oxidize and form an insulating layer. Moreover, the anode 192 of the organic light emitting diode 190 and the source/drain electrode 170 can be electrically coupled by an electrically conductive via 198 penetrating through the insulating layer 180 (the protective layer 182 and the planarization layer 184). In addition, although the embodiment of FIG. 2a has been described based on a top emission system in which the light is emitted in the direction from the lower part to the upper part of the substrate 110, the present invention can be applied to a bottom emission system in which the light is emitted in the direction from the upper part to the lower part of the substrate 110 or a dual emission system in which the light is simultaneously emitted in the directions from the lower part to the upper part and from the upper part to the lower part of the substrate 110.

The pixel defining layer 200 can be formed on the top surface of the insulating layer 180 at the outer circumference of the organic light emitting diode 190. The pixel defining layer 200 defines boundaries between a red organic light emitting diode, a green organic light emitting diode and a blue organic light emitting diode, and thus defines light emitting boundary regions between pixels. Moreover, the pixel defining layer 200 can be formed of any material selected from polyimide and its equivalent, but not limited thereto.

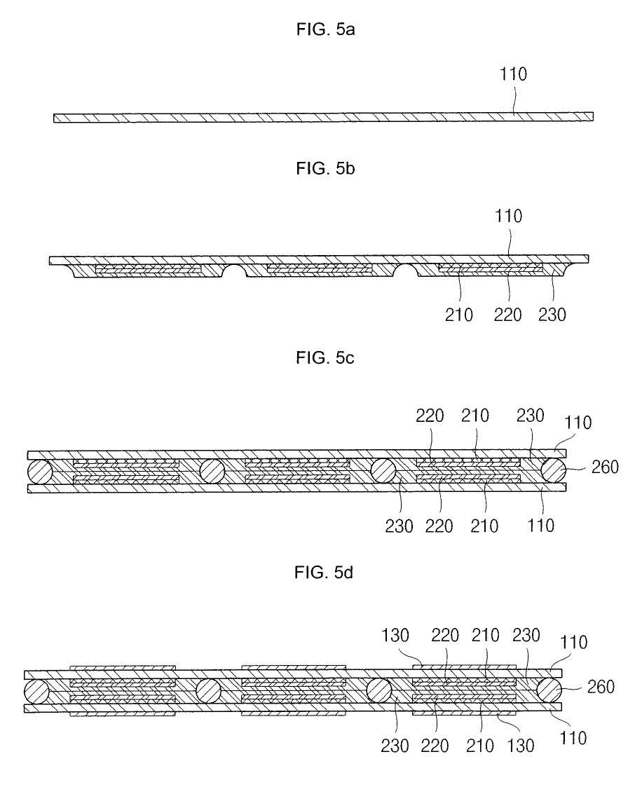

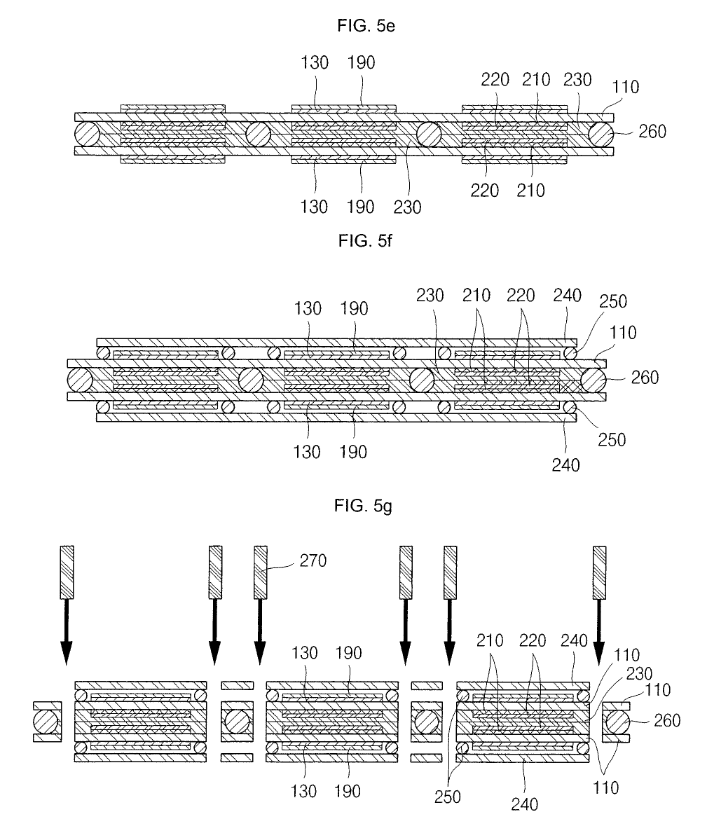

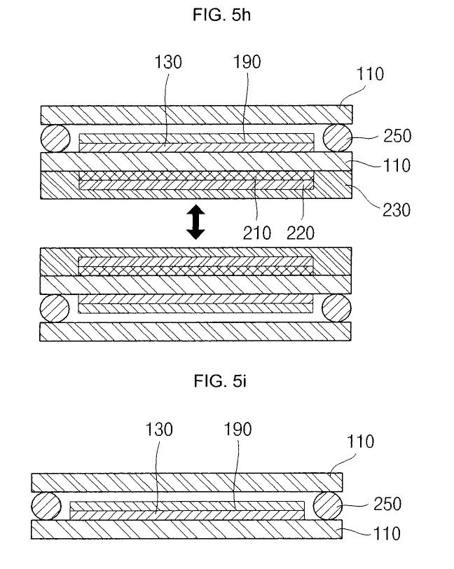

Next, as shown in FIG. 2b, the organic light emitting display 102 is substantially the same as the organic light emitting display 101, but is further provided on the bottom surface of the substrate 110 with a non-transmissive layer 210. The non-transmissive layer 210 is for blocking (or preventing) the UV-ray (ultraviolet ray) from transmitting (or substantially transmitting) to an another substrate 110 opposing the substrate 110 provided with the non-transmissive layer 210 when forming the semiconductor layer 130 and the organic light emitting diode 190 and so on by bonding the two substrates 110 (as described in more detail below, e.g., as shown in FIG. 5h). In one embodiment, the non-transmissive layer 210 is also for blocking (or preventing) the external UV-ray from transmitting (or substantially transmitting) to the semiconductor layer 130 and/or the organic light emitting diode 190 after the two substrates 110 are separated from each other. That is, in one embodiment, the non-transmissive layer 210 is for shielding the another substrate 110 from the UV-ray (ultraviolet ray) and/or for shielding the semiconductor layer 130 and/or the organic light emitting diode 190 from the external UV-ray. The non-transmissive layer 210 can be substantially formed of any suitable material having a UV-ray protective agent and its equivalent. Moreover, the non-transmissive layer 210 can also be formed of any material having a metal that does not transmit the UV-ray, a transparent UV-ray protective agent, an opaque UV-ray protective agent and/or their equivalents. Furthermore, if the non-transmissive layer 210 is a metal, it can be formed of any material selected from chrome (Cr), chrome oxide (Cr₂O₃), aluminum (Al), gold (Au), silver (Ag), magnesium oxide (MgO), silver alloy and their equivalents, but not limited thereto. In one embodiment, the thickness of the non-transmissive layer 210 is from 500 Å to 3000 Å. In one embodiment, if the thickness of the non-transmissive layer 210 is below 500 Å, then the UV-ray protection factor is low, thereby affecting the semiconductor layer 130 or the organic light emitting diode 190 during or after a fabricating process. In another embodiment, if the thickness of the non-transmissive layer 210 is above 3000 Å, then the non-transmissive layer excessively thickens without adding to any advantageous increase to the UV-ray protection factor.

Furthermore, as shown in FIG. 2c, the organic light emitting display 103 is substantially the same as the organic light emitting display 102, but is further provided on the bottom surface of the non-transmissive layer 210 with a magnetic layer 220. The magnetic layer 220 is for blocking (or preventing) the substrate 110 from warping when forming the semiconductor layer 130 and the organic light emitting diode 190 and so on by using the two substrates 110 (as described in more detail below). That is, the substrate 110 is blocked from being warped (or from having a warpage) by positioning a magnet, which has the same polarity to the magnetic layer 220 to repulse the polarity of the magnetic layer 220, on the bottom surface of the substrate 110. The magnetic layer 220 can be formed of at least one magnet selected from an AlNiCo magnet, a ferrite magnet, a rare-earth magnet, a rubber magnet, a plastic magnet and their equivalents, but not limited thereto. That is, according to one embodiment of the present invention, an electromagnet that is not a permanent magnet can be formed on the bottom surface of the non-transmissive layer 210 or a pattern of an electromagnet can be formed thereon, and thus they can be substituted for the magnetic layer. In one embodiment, the thickness of the magnetic layer 220 is from 10 μm to 100 μm. In one embodiment, if the thickness of the magnetic layer 220 is below 10 μm, then it is difficult to obtain a magnetic force that is sufficient for blocking (or preventing) the warping (or warpaging) of the substrate 110 during a fabricating process. In another embodiment, if the thickness of the magnetic layer 220 is above 100 μm, then the magnetic layer excessively thickens.

Furthermore, as shown in FIG. 2d, the organic light emitting display 104 is substantially the same as the organic light emitting display 103, but is further provided on the bottom surface of the magnetic layer 220 with an anti-friction layer 230. The anti-friction layer 230 is for blocking (or preventing) two substrates 110 from contacting with each other when forming the semiconductor layer 130 and the organic light emitting diode 190 and so on by bonding the two substrates 110 (as described in more detail below). That is, the non-transmissive layer 210 or the magnetic layer 220 formed on the two substrates 110 are not allowed to contact with each other, thereby blocking (or preventing) damage to the substrates 110. The anti-friction layer 230 can be formed of any material selected from an organic material, an inorganic material and their equivalents, but not limited thereto. Moreover, in one embodiment, the thickness of the anti-friction layer 230 is from 10 μm to 100 μm. In one embodiment, if the thickness of the anti-friction layer 230 is below 10 μm, then the non-transmissive layer 210 or the magnetic layer 220 of the substrate 110 can contact with that of the another substrate 110. In another embodiment, if the thickness of the anti-friction layer 230 is above 100 μm, the total thickness of the substrate 110 becomes excessively large.

Furthermore, as shown in FIG. 2e, the organic light emitting display 105 is substantially the same as the organic light emitting display 104, but is provided on the bottom surface of the substrate 110 with the non-transmissive layer 210 and the anti-friction layer 230 (and without the magnetic layer 220). Since the materials and thicknesses of the non-transmissive layer 210 and the anti-friction layer 230 have been described as above, the explanations about them will not be provided again. Here, if the area of the substrate 110 is small and thus there is nearly no probability that the substrate 110 can warp (or warpage), then it is possible for the magnetic layer 220 not to position between the non-transmissive layer 210 and the anti-friction layer 230. In one embodiment, the magnetic layer 220 can be omitted in all organic light emitting displays. That is, if the non-transmissive layer 210 and the anti-friction layer 230 are formed relatively thick in a permissible range, then the rigidity of the bonded substrate 110 is raised, and thus the substrate may not be warped during various fabricating processes.

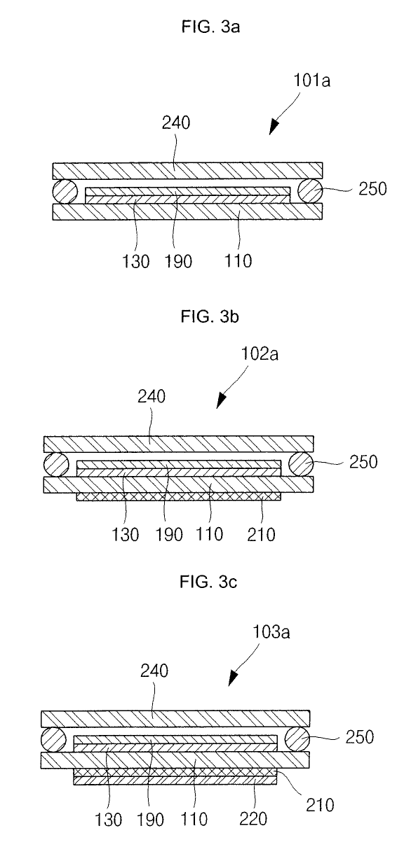

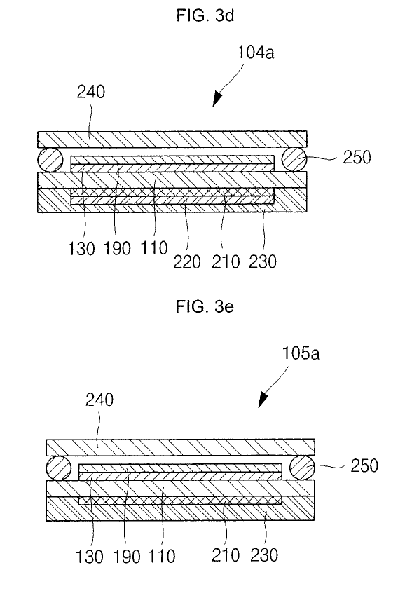

FIGS. 3a to 3e are views showing organic light emitting displays with encapsulation substrates respectively attached thereto according to embodiments of the present invention.

As shown in FIG. 3a, an organic light emitting display 101a according to an embodiment of the present invention can be formed by forming the semiconductor layer 130, the organic light emitting diode 190 and so forth on the surface of the substrate 110 and then attaching an encapsulation substrate 240 thereto. In one embodiment, an encapsulant 235 is interposed between the substrate 110 and the encapsulation substrate 240. The encapsulation substrate 240 can be formed of any material selected from glass, plastic, polymer and their equivalents, but not limited thereto. Moreover, the encapsulant 235 may be at least one adhesive selected from an epoxy adhesive, a UV-ray setting adhesive, a frit and their equivalents, but not limited thereto. If the frit is used as the encapsulant 235, then it is necessary to heat the frit at a temperature (which may be predetermined), and thus an encapsulation operation can be performed using a laser beam (e.g., to provide the heat). That is, when the frit is positioned between the substrate 110 and the encapsulation substrate 240 and then is irradiated by a laser beam at one side, the frit is melted, and thus the substrate 110 is strongly attached to the encapsulation substrate 240.

Also, as shown in FIG. 3b, an organic light emitting display 102a according to an embodiment of the present invention can be further provided on the bottom surface of the substrate 110 with the non-transmissive layer 210.

Moreover, as shown in FIG. 3c, an organic light emitting display 103a according to an embodiment of the present invention can be sequentially provided on the bottom surface of the substrate 110 with the non-transmissive layer 210 and the magnetic layer 220.

Furthermore, as shown in FIG. 3d, an organic light emitting display 104a according to an embodiment of the present invention can be sequentially provided on the bottom surface of the substrate 110 with the non-transmissive layer 210, the magnetic layer 220 and the anti-friction layer 230.

In addition, as shown in FIG. 3e, an organic light emitting display 105a according to an embodiment of the present invention can be sequentially provided on the bottom surface of the substrate 110 with the non-transmissive layer 210 and the anti-friction layer 230.

Since the non-transmissive layer 210, the magnetic layer 220 and the anti-friction layer 230 formed on the bottom surface of the substrate 110 have been described as above, the explanation about them will not be provided again.

Moreover, the bottom surface of the encapsulation substrate 240 can be further provided with a transparent moisture absorption layer. That is, since the organic light emitting diode 190 is vulnerable to moisture, the transparent moisture absorption layer, which does not block the transmission of the light and can absorb moisture, can be formed on the bottom surface of the encapsulation substrate 240. In one embodiment, the transparent moisture absorption layer can become (or grow) thicker (e.g., as it absorbs moisture) as long as the transparency of the encapsulation substrate 240 is ensured, and, in one embodiment, the thickness of the transparent moisture absorption layer is from 0.1 μm to 300 μm. In one embodiment, if the thickness of the transparent moisture absorption layer is below 0.1 μm, then the transparent moisture absorption layer does not have a sufficient moisture absorption characteristic. In another embodiment, if the thickness of the transparent moisture absorption layer is above 300 μm, then the transparent moisture absorption layer can be in danger of contacting the organic light emitting diode 190. Moreover, the transparent moisture absorption layer can be formed of at least one material selected from, but not limited thereto, an alkali metal oxide, an alkaline-earth metal oxide, a metal halide, a metal sulfate and a metal perchlorate, a phosphorus pentoxide (P₂O₅) and their equivalents, and, in one embodiment, the average particle diameter of which is below 100 nm and, in one embodiment, is from 20 nm to 100 nm.

Moreover, according to one embodiment of the present invention, it is possible to absorb moisture by filling a space between the substrate 110 and the encapsulation substrate 240 with at least one material selected from a layered inorganic substance, a polymer, a hardening agent and their equivalents instead of forming the transparent moisture absorption layer on the encapsulation substrate 240. In one embodiment, after filling the space with the material, a heat treatment process is performed to harden the material.

Furthermore, according to one embodiment of the present invention, a polarizer film can be attached to the surface of each encapsulation substrate 240 to block (or prevent) the light reflection phenomenon due to an external light.

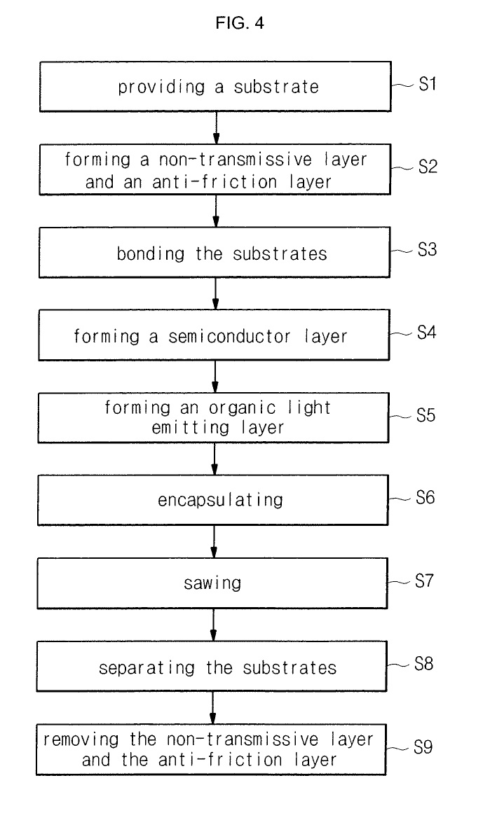

FIG. 4 is a flow chart showing a fabricating method of an organic light emitting display according to an embodiment of the present invention.

As shown in FIG. 4, the fabricating method includes: a step of providing a substrate S1; a step of forming a non-transmissive layer S2; a step of bonding the substrates (e.g., bonding a first substrate 110 with a second or another substrate 110) S3; a step of forming a semiconductor layer S4; a step of forming an organic light emitting diode S5; a step of attaching an encapsulation substrate S6; a step of cutting (or sawing) S7; a step of separating the substrates S8; and a step of removing the non-transmissive layer (and/or the anti-friction layer) S9.

FIGS. 5a to 5i are views showing a fabricating sequence of an organic light emitting display according to an embodiment of the present invention. Hereinafter, a fabricating method of an organic light emitting display according to an embodiment of the present invention will be sequentially described.

As shown in FIG. 5a, in the step of preparing the substrate S1, the substrate 110 is provided, which has substantially flat top and bottom surfaces and a thickness (which may be predetermined).

In one embodiment, the thickness of the substrate 110 is from about 0.05 mm to about 1 mm. In one embodiment, if the thickness of the substrate 110 is below about 0.05 mm, the substrate 110 may be damaged due to cleaning, etching and heat treatment processes during a fabricating process and has a low strength against an external force and it is difficult to handle the substrate. In another embodiment, if the thickness of the substrate 110 is above about 1 mm, it is difficult to apply the substrate 110 to various display devices that are to be thin (or slim). Furthermore, the substrate 110 can be formed of any material selected from ordinary glass, plastic, polymer, steel and their equivalents, but not limited thereto.

As shown in FIG. 5b, in the step of forming the non-transmissive layer S2, the non-transmissive layer 210 having a thickness (which may be predetermined) is formed on the bottom surface of the substrate 110.

The non-transmissive layer 210 is for blocking (or preventing) the UV-ray (ultraviolet ray) from transmitting (or substantially transmitting) to another substrate 110 opposing the substrate 110 provided with the non-transmissive layer 210 when forming the semiconductor layer and the organic light emitting diode and so on by bonding the two substrates 110. In one embodiment, the non-transmissive layer 210 is also for blocking (or preventing) the external UV-ray from transmitting (or substantially transmitting) to the semiconductor layer and/or the organic light emitting diode after the two substrates 110 are separated from each other. The non-transmissive layer 210 can be substantially formed by coating at least one material having a UV-ray protective agent and its equivalent on the surface of the substrate 110. Moreover, the non-transmissive layer 210 can also be formed by depositing or coating at least one material having a metal that does not transmit the UV-ray, a transparent UV-ray protective agent, an opaque UV-ray protective agent and/or their equivalents on the surface of the substrate 110. Furthermore, if the non-transmissive layer 210 is a metal, it can be formed by depositing or coating at least one material selected from chrome (Cr), chrome oxide (Cr₂O₃), aluminum (Al), gold (Au), silver (Ag), magnesium oxide (MgO), silver alloy and their equivalents on the surface of the substrate 110. In one embodiment, the thickness of the non-transmissive layer 210 is from 500 Å to 3000 Å. In one embodiment, if the thickness of the non-transmissive layer 210 is below 500 Å, then the UV-ray protection factor is low, thereby affecting the semiconductor layer or the organic light emitting diode during or after a fabricating process. In another embodiment, if the thickness of the non-transmissive layer 210 is above 3000 Å, then the non-transmissive layer excessively thickens without adding to any advantageous increase to the UV-ray protection factor (i.e., the UV-ray protection factor is sufficient below 3000 Å).

Furthermore, in the step of forming the non-transmissive layer S2, the magnetic layer 220 can be formed on the bottom surface of the non-transmissive layer 210, or the magnetic layer 220 and the anti-friction layer 230 can be sequentially formed on the bottom surface of the non-transmissive layer 210, or the anti-friction layer 230 can be further formed on the bottom surface of the non-transmissive layer 210.

Here, the magnetic layer 220 is for blocking (or preventing) the substrate 110 from warping (warpaging) when forming the semiconductor layer 130 and the organic light emitting diode 190 and so on when bonding the two substrates 110. That is, the substrate 110 is blocked from being warped (or from having a warpage) by positioning a magnet, which has the same polarity to the magnetic layer 220 to repulse the polarity of the magnetic layer 220, on the bottom surface of the substrate 110 during a fabricating process. The magnetic layer 220 can be formed of at least one magnet selected from an AlNiCo magnet, a ferrite magnet, a rare-earth magnet, a rubber magnet, a plastic magnet and their equivalents, but not limited thereto. In one embodiment, an electromagnet is used as the magnetic layer 220. In one embodiment, the thickness of the magnetic layer 220 is from 10 μm to 100 μm. In one embodiment, if the thickness of the magnetic layer 220 is below 10 μm, then it is difficult to obtain a magnetic force that is sufficient for blocking (or preventing) the warping of the substrate 110 during a fabricating process. In another embodiment, if the thickness of the magnetic layer 220 is above 100 μm, then the magnetic layer excessively thickens. Furthermore, the anti-friction layer 230 is for blocking (or preventing) two substrates 110 from contacting with each other when forming the semiconductor layer and the organic light emitting diode and so on by bonding the two substrates 110. That is, the non-transmissive layers 210 or the magnetic layers 220 formed on the two substrates 110 are not allowed to contact with each other, thereby reducing (or preventing) damage of the substrates 110. The anti-friction layer 230 can be formed of at least one material selected from an organic material, an inorganic material and their equivalents, but not limited thereto. Moreover, in one embodiment, the thickness of the anti-friction layer 230 is from 10 μm to 100 μm. In one embodiment, if the thickness of the anti-friction layer 230 is below 10 μm, then the non-transmissive layer 210 or the magnetic layer 220 of the substrate 110 can contact with that of the another substrate 110. In another embodiment, if the thickness of the anti-friction layer 230 is above 100 μm, the total thickness of the substrate 110 becomes excessively large.

As shown in FIG. 5c, in the step of bonding the substrates S3, two identical (or substantially identical) substrates 110, on which the non-transmissive layer 210; the non-transmissive layer 210 and the magnetic layer 220, the non-transmissive layer 210, the magnetic layer 220 and the anti-friction layer 230, or the non-transmissive layer 210 and the anti-friction layer 230 are formed, are provided and bonded to each other. Here, FIG. 5c shows that the non-transmissive layer 210, the magnetic layer 220 and the anti-friction layer 230 are sequentially formed on each of the substrates 110.

Also, a bonding agent 260 can be interposed between the two substrates 110 so that the substrates 110 cannot be separated from each other during a bonding process. The bonding agent 260 can be formed by at least one adhesive selected from an ordinary epoxy adhesive, a UV-ray setting adhesive and their equivalents, but not limited thereto. Moreover, the bonding agent 260 can be formed only on the edge portion (or edge) of one or more of the substrates 110, or the bonding agent can be formed on inner circumferences of each of the two substrates 110 in the form of a plurality of lines so as to bond the substrates 110 to each other more stably. FIG. 5c shows that a plurality of bonding agents (e.g., four bonding agents) 260 are formed between the two substrates 110.

Furthermore, the anti-friction layer 230 can be formed not in the step S2 of forming the non-transmissive layer 110 but in the step S3 of bonding the substrates 110. That is, if the two substrates 110 are bonded to each other by interposing the bonding agent 260 between them and then the liquid anti-friction layer 230 is injected between the two substrates 210, the liquid anti-friction layer permeates into a gap formed between two substrates 110 by a capillary phenomenon. In one embodiment, after forming the liquid anti-friction layer 230, the liquid anti-friction layer 230 is cured by heat-treating the substrates 110 at a temperature, which may be predetermined. Moreover, in one embodiment, in the step S3 of bonding the substrates 110, anti-friction layers 230 formed on the two substrates 110 are bonded to each other. That is, in one embodiment, the anti-friction layers 230 are formed on the two substrates 110 are closely contacted with each other so as to block (or prevent) the substrates 110 from warping or rubbing with each other during a movement of the bonded substrates 110.

As shown in FIG. 5d, in the step S4 of forming the semiconductor layer, semiconductor layers 130 are formed on surfaces of the two substrates 110 bonded to each other. That is, the semiconductor layers 130 for driving the organic light emitting display are respectively formed on the surfaces of the two substrates 110 that are opposite to surfaces on which the anti-friction layers 230 are formed. In one embodiment, a buffer layer can be formed on the surface of the substrate 110 before forming the semiconductor layer 130. Moreover, after forming the semiconductor layer 130, a gate insulating layer, a gate electrode, an inter-layer dielectric layer, a source/drain electrode, an insulating layer and so forth are formed. Since such a constitution has been described as above, the explanation thereabout will not be provided again.

The semiconductor layers 130 can be respectively formed on one substrate 110 and then on the other substrate 110. That is, one semiconductor layer 130 can be formed on one substrate 110 and the other semiconductor layer 130 can be formed on the other substrate 110 (or vise versa). Furthermore, the semiconductor layers 130 can be simultaneously (or concurrently) formed on the two substrates 110 if a process equipment permits.

As shown in FIG. 5e, in the step S5 of forming the organic light emitting diode, organic light emitting diodes 190 are formed on top surfaces of respective semiconductor layers 130. More specifically, an anode, an organic thin layer and a cathode are sequentially formed on an insulating layer as described above. In one embodiment, after forming the organic light emitting diode 190, the pixel defining layer 200 is formed. Here, since the structure and forming method of the organic light emitting diode 190 have been described as above, the explanation about them will not be provided again.

The organic light emitting diodes 190 can be respectively formed on one substrate 110 and then on the other substrate 110. That is, one organic light emitting diode 190 can be formed on one substrate 110 and the other organic light emitting diode 190 can be formed on the other substrate 110 (or vise versa). Furthermore, the organic light emitting diodes 190 can be simultaneously (or concurrently) formed on the two substrates 110 if a process equipment permits.

As shown in FIG. 5f, in the step S6 of attaching the encapsulation substrate, encapsulation substrates 240 are attached by encapsulants 235 to surfaces on which the semiconductor layers 130 and the organic light emitting diodes 190 are formed. Here, the encapsulation substrates 240 can be formed of any material selected from ordinary glass, plastic, polymer and their equivalents, but not limited thereto. In one embodiment, the area of the encapsulation substrate 240 is substantially smaller than that of the substrate 110. More specifically, the edges of the encapsulation substrate 240 (e.g., at least two opposite edges of the encapsulation substrate 240) can be shorter by 3 cm to 8 cm in an inward direction of that of the substrate 110, and thus the edge portion (or edge) of the substrate 110 can be readily sawn in the following cutting (or sawing) process. Furthermore, the encapsulant 235 can be formed by at least one adhesive selected from an epoxy adhesive, a UV-ray setting adhesive, a frit and their equivalents, but not limited thereto. In addition, if the frit is used as the encapsulant 235, then it is necessary to heat the frit at a temperature (which may be predetermined), and thus an encapsulation operation can be performed using a laser beam.

Furthermore, although the integrated encapsulation substrate 240 is shown in FIG. 5f, an encapsulation process can be performed by encapsulating each region on which each semiconductor layer 130 and organic light emitting diode 190 is formed by the respective encapsulation substrate 240. In this embodiment, since each encapsulation substrate 240 should be attached by the respective encapsulants 235, the number of operation processes may be increased.

Also, the bottom surface of the encapsulation substrate 240 can be further provided with the transparent moisture absorption layer. That is, since the organic light emitting diode 190 is vulnerable to moisture, the transparent moisture absorption layer, which does not block the transmission of the light and can absorb moisture, can be formed on the bottom surface of the encapsulation substrate 240. In one embodiment, the transparent moisture absorption layer can become (or grow) thicker as long as the transparency of the encapsulation substrate 240 is ensured, and, in one embodiment, the thickness of the transparent moisture absorption layer is from 0.1 μm to 300 μm. In one embodiment, if the thickness of the transparent moisture absorption layer is below 0.1 μm, then the transparent moisture absorption layer does not have a sufficient moisture absorption characteristic. In another embodiment, if the thickness of the transparent moisture absorption layer is above 300 μm, then the transparent moisture absorption layer can be in a danger of contacting the organic light emitting diode 190. Moreover, the transparent moisture absorption layer can be formed of at least one material selected from, but not limited thereto, an alkali metal oxide, an alkaline-earth metal oxide, a metal halide, a metal sulfate and a metal perchlorate, a phosphorus pentoxide (P₂O₅) and their equivalents, and, in one embodiment, the average particle diameter of which is below 100 nm and, in one embodiment, is from 20 nm to 100 nm.

Furthermore, according to one embodiment of the present invention, it is possible to carry out an encapsulation process by filling a space between the substrate 110 and the encapsulation substrate 240 with at least one material selected from a layered inorganic substance, a polymer, a hardening agent and their equivalents instead of forming the transparent moisture absorption layer on the encapsulation substrate 240. In one embodiment, after filling the space with the material, a heat treatment process is performed to harden the material.

Furthermore, according to one embodiment of the present invention, a polarizer film can be attached to the surface of each encapsulation substrate 240 to block (or prevent) the light reflection phenomenon due to an external light.

As shown in FIG. 5g, in the step S7 of cutting (or sawing), the substrates 110 are sawn so as to separate into the respective units of organic light emitting display. That is, in the step of cutting, the substrates 110 and the encapsulation substrates 240 that are positioned on the outer circumference of the semiconductor layers 130 and the organic light emitting diodes 190 can be sawn together. As described above, in one embodiment, each encapsulation substrate 240 can be attached only to the region that corresponds to each semiconductor layer 130 and each organic light emitting diode 190, and each unit of the organic light emitting display can be obtained by cutting only the corresponding substrate 110.

Furthermore, due to the step of cutting, the bonding agent 260 bonding the substrates 110 to each other is removed. In one embodiment, during the cutting process, it is also possible for the bonding agent 260 itself to be cut (or sawn), and a portion of the bonding agent 260 can remain on the cut (or sawn) substrate 110. Moreover, such a cutting operation can be performed by at least one mechanism selected from a diamond wheel, a laser beam and their equivalents, but not limited thereto. In FIG. 5g, one or more laser beam emitters 270 are shown.

As shown in FIG. 5h, in the step S8 of separating the substrates, the two substrates 110 that have been sawn are separated from each other. In one embodiment, each of the separated substrates 110 is provided with the non-transmissive layer 210; the non-transmissive layer 210 and the magnetic layer 220; the non-transmissive layer 210, the magnetic layer 220 and the anti-friction layer 230; or the non-transmissive layer 210 and the anti-friction layer 230. Referring to FIG. 5h, the bottom surface of the substrate 110 is provided with the non-transmissive layer 210, the magnetic layer 220 and the anti-friction layer 230.

Here, if each anti-friction layer 230 is formed on each substrate 110 before the step of bonding the substrates, then the substrates can be readily separated from each other.

However, if the liquid anti-friction layer 230 is injected after bonding the substrates 110, then the substrates may not be readily separated from each other. Hence, in this case, the anti-friction layer 230 is removed by a chemical solution that can dissolve the anti-friction layer 230. For this purpose, in one embodiment, the anti-friction layer 230 is formed of an organic material that can readily dissolve by a chemical solution.

According to an embodiment of the present invention, the step of separating the substrates 110 can be the last step. That is, after the step of separating the substrates 110, it is possible to deliver as a product by making a cell test, a FPC (Flexible Printed Circuit) bonding, a module test and a reliability test. In one embodiment, the cell test can also be performed by separately forming a test region for the cell test before the cutting step.

Also, if the step of separating the substrates 110 is employed as the last step, the finished organic light emitting display (e.g., the organic light emitting display 101) can be provided with the non-transmissive layer 210; the non-transmissive layer 210 and the magnetic layer 220; the non-transmissive layer 210, the magnetic layer 220 and the anti-friction layer 230; or the non-transmissive layer 210 and the anti-friction layer 230.

As shown in FIG. 5i, in the step S9 of removing the non-transmissive layer, the non-transmissive layer 210 can be removed by an etching or grinding operation. More specifically, if only the non-transmissive layer 210 was formed on the bottom surface of the substrate 110, then the non-transmissive layer 210 is removed. Moreover, if the non-transmissive layer 210 and the magnetic layer 220 were formed on the bottom surface of the substrate 110, only the magnetic layer 220 can be removed, or the non-transmissive layer 210 and the magnetic layer 220 can be removed together. Furthermore, if the non-transmissive layer 210, the magnetic layer 220, and the anti-friction layer 230 were formed on the bottom surface of the substrate 110, only the anti-friction layer 230 can be removed, the anti-friction layer 230 and the magnetic layer 220 can be removed together, or the anti-friction layer 230, the magnetic layer 220 and the non-transmissive layer 210 can be removed together. In one embodiment, if the non-transmissive layer 210 and the anti-friction layer 230 were formed on the bottom surface of the substrate 110, only the anti-friction layer 230 can be removed, or the anti-friction layer 230/the non-transmissive layer 210 can be removed together.

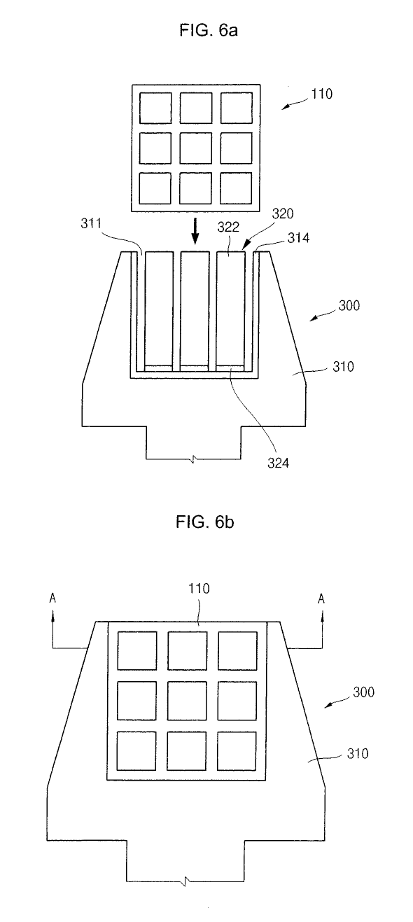

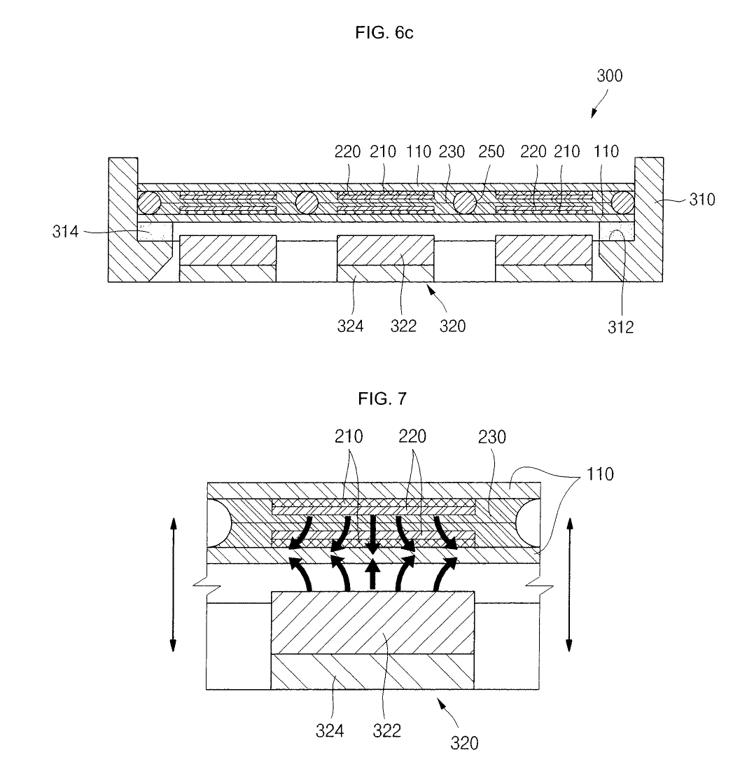

FIGS. 6a and 6b are top views of a moving device for an organic light emitting display according to an embodiment of the present invention, and FIG. 6c is a sectional view taken along the line A-A of FIG. 6b.

As shown in FIGS. 6a and 6b, a moving device 300 for an organic light emitting display includes a moving body 310 and a shock-absorbing member 320.

Referring now also to FIG. 6c, one or more openings 311 are formed on one side of the moving body 310, and a step 312 having a depth (which may be predetermined) is formed along the circumference of the opening 311 so as to receive the two bonded substrates 110. Moreover, an anti-slide pad 314 can be further formed on the step 312 so as to receive the bonded substrates 110 and to prevent (or hinder) the substrates 110 from sliding during the transfer thereof. The anti-slide pad 314 can be formed of any material selected from ordinary rubber, silicon and their equivalents, but not limited thereto.

Furthermore, the shock-absorbing member 320 extends from the step 312 of the moving body 310 by a length (which may be predetermined) so as to block (or prevent) the bonded substrates 110 from warping in the lower direction due to the weight of the substrates 110. A magnet 322 can be further attached to the region of the shock-absorbing member 320 that faces the bonded substrates 110. Hence, if the magnetic layer 220 is formed on the bonded substrates 110, then it repulses the magnet 322 of the shock-absorbing member 320. For this purpose, the magnetic layer 220 formed on the bonded substrates 110 and the magnet 322 mounted on the shock-absorbing member 320 should have the same polarity. Moreover, the magnet 322 formed on the shock-absorbing member 320 may be a permanent magnet or an electromagnet, but not limited thereto.

In addition, one or more elastic parts 324 can be provided on the boundary between the shock-absorbing member 320 and the moving body 310 so that the shock-absorbing member 320 itself can be moved (e.g., upwardly and downwardly moved) by a distance (which may be predetermined). That is, when the moving device 300 performs a transfer operation, the moving device 300 can vibrate due to an external force or a vibration of the moving device itself. Hence, the substrate 110 received in the moving device 300 also vibrates. Here, since the magnet 322 of the shock-absorbing member 320 repulses the magnetic layer 220 of the substrate 110, the shock-absorbing member 320 can also be moved (e.g., upwardly and downwardly moved) by a distance (which may be predetermined) due to the elastic part 324. For this purpose, the elastic part 324 can be formed by at least one mechanism selected from a spring, an air cylinder, a shock-absorbing pad and their equivalents that are formed on the coupling region with the moving body 310, but not limited thereto.

FIG. 7 shows a state in which a substrate is supported by a shock-absorbing member in a moving device according to an embodiment of the present invention.

As shown in FIG. 7, the magnetic layers 220 are formed on the surfaces of the substrates 110 that face each other. Moreover, the shock-absorbing member 320 with the magnet 322 attached thereto is positioned in the lower region that corresponds to the magnetic layers. Hence, if the vibration does not occur, then the magnetic layer 220 of the substrate 110 repulses the magnet 322 of the shock-absorbing member 320, and thus the shock-absorbing member 320 blocks or prevents the center of the substrate 110 from warping (e.g., warping downwardly in a non-contact manner).

Also, if the vibration is occurring during transfer operation, then the substrate 110 vibrates, and thus the shock-absorbing member 320 also vibrates (e.g., upwardly and downwardly vibrates). That is, the shock-absorbing member 320 is also moved in the vibration direction of the substrate 110 by the elastic part 324 formed on the shock-absorbing member 320. Hence, the shock-absorbing member 320 is not brought into contact with the surface of the substrate 110, and thus the damage of the substrate 110 is blocked (or prevented).

An organic light emitting display according to an embodiment of the present invention can be readily applied to various electronic display devices, such as a cellular phone, a PDA, a notebook, a computer monitor and a television that are thin (or slim), by forming the organic light emitting display on a substrate having a thickness of from 0.05 mm to 1 mm.

Moreover, in one embodiment, the organic light emitting display can block (or prevent) a UV-ray from affecting a semiconductor layer and/or an organic light emitting diode through the substrate during use by forming a non-transmissive layer on the substrate.

A fabricating method of an organic light emitting display according to an embodiment of the present invention can reduce an entire processing time by about 50% by bonding two substrates having (or each having) the thickness of from 0.05 mm to 1 mm and performing simultaneously (or concurrently) a semiconductor forming process and an organic thin layer forming process (in one embodiment, each process includes a cleaning operation, an etching operation, a light exposure operation, a development operation, a heat treatment operation and so on).

Moreover, the fabricating method can block (or prevent) a UV-ray due to a light exposure operation during a fabricating process from affecting another opposing organic light emitting display by forming the non-transmissive layer on the bottom surface of the substrate.

Furthermore, the fabricating method can block (or prevent) the organic light emitting display from warping or being damaged due to gravity by the repulsive force between the magnetic layer and the moving device moving the magnetic layer during a fabricating process by forming the non-transmissive layer and the magnetic layer on the bottom surface of the substrate.

In addition, the fabricating method can block (or prevent) the substrates or the metals formed on the surfaces of the substrates from contacting with each other when bonding the two substrates and thus can block (or prevent) the damage of the substrate by forming the non-transmissive layer, the magnetic layer and the anti-friction layer or the non-transmissive layer and the anti-friction layer on the bottom surface of the substrate.

A moving device of the organic light emitting display according to an embodiment of the present invention can block or prevent the substrate from warping or being damaged, by supporting the edge portion of the substrate on which a semiconductor layer and/or an organic light emitting diode are not formed by an anti-slide pad having a relatively high elasticity, and by supporting the central region of the substrate on which the semiconductor layer and/or the organic light emitting diode are formed by a shock-absorbing member in a non-contact manner.

Moreover, the moving device can block or prevent the central region of the substrate, which is not supported by the anti-slide pad, from contacting with the shock-absorbing member and can maintain the flat state of the central region of the substrate during transfer or process, by mounting the magnet on the shock-absorbing member so as to repulse the magnetic layer formed on the two bonded substrates.

While the invention has been described in connection with certain exemplary embodiments, it will be appreciated by those skilled in the art that the invention is not limited to the disclosed embodiments, but, on the contrary, is intended to cover various modifications included within the principles and spirit of the invention, the scope of which is defined in the claims and their equivalents.

What is claimed is:

1. An organic light emitting display comprising:
a substrate having a first surface and a second surface;
an organic light emitting diode, an insulating layer and a semiconductor layer disposed on the first surface of the substrate, the insulating layer being disposed between the organic light emitting diode and the semiconductor layer; and
a non-transmissive layer disposed on the second surface of the substrate,
wherein the non-transmissive layer is adapted to block a UV-ray.

2. The organic light emitting display as claimed in claim 1, further comprising:
a buffer layer disposed on the first surface of the substrate, the semiconductor layer being disposed on the buffer layer;
a gate insulating layer disposed on the semiconductor layer;
a gate electrode disposed on the gate insulating layer;
an inter-layer dielectric layer disposed on the gate electrode; and
a source/drain electrode disposed on the inter-layer dielectric layer, the insulating layer being disposed on the source/drain electrode and the organic light emitting diode being disposed on the insulating layer.

3. The organic light emitting display as claimed in claim 2, wherein the substrate has a thickness ranging from about 0.05 mm to about 1 mm.

4. The organic light emitting display as claimed in claim 2, wherein the substrate comprises a material selected from the group consisting of glass, plastic, polymer, steel, and combinations thereof.

5. The organic light emitting display as claimed in claim 2, wherein the non-transmissive layer has a thickness ranging from about 500 Å to about 3000 Å.

6. The organic light emitting display as claimed in claim 2, wherein the non-transmissive layer comprises a UV-ray protective agent.

7. The organic light emitting display as claimed in claim 2, wherein the non-transmissive layer comprises a material selected from the group consisting of a metal that does not transmit the UV-ray, a transparent UV-ray protective agent, an opaque UV-ray protective agent, and combinations thereof.

8. The organic light emitting display as claimed in claim 2, wherein the non-transmissive layer comprises a material selected from the group consisting of chrome (Cr), chrome oxide (Cr₂O₃), aluminum (Al), gold (Au), silver (Ag), magnesium oxide (MgO), silver alloy, and combinations thereof.

9. The organic light emitting display as claimed in claim 2, further comprising a magnetic layer disposed on a bottom surface of the non-transmissive layer.

10. The organic light emitting display as claimed in claim 9, wherein the thickness of the magnetic layer has a thickness ranging from 10 μm to 100 μm.

11. The organic light emitting display as claimed in claim 9, wherein an anti-friction layer is further formed on a bottom surface of the magnetic layer.

12. The organic light emitting display as claimed in claim 2, further comprising an anti-friction layer disposed on a bottom surface of the non-transmissive layer.

13. The organic light emitting display as claimed in claim 12, wherein the anti-friction layer has a thickness ranging from about 10 μm to about 100 μm.

14. The organic light emitting display as claimed in claim 12, wherein the anti-friction layer comprises a material selected from the group consisting of an organic material and an inorganic material.

15. The organic light emitting display as claimed in claim 2, further comprising an encapsulant disposed on a circumference of the first surface of the substrate, and an encapsulation substrate attached to the encapsulant.

16. The organic light emitting display as claimed in claim 1, further comprising:
a buffer layer disposed on the first surface of the substrate, the gate electrode being disposed on the buffer layer;
a gate insulating layer disposed on the gate electrode;
a semiconductor layer disposed on the gate insulating layer;
an inter-layer dielectric layer disposed on the semiconductor layer; and
a source/drain electrode disposed on the inter-layer dielectric layer, the insulating layer being disposed on the source/drain electrode and the organic light emitting diode being disposed on the insulating layer.

17. A fabricating method of an organic light emitting display, the method comprising:
providing a first substrate and a second substrate;
forming a first non-transmissive layer on a bottom surface of the first substrate;
forming a second non-transmissive layer on a bottom surface of the second substrate;
bonding the first substrate with the second substrate so that the first and second non-transmissive layers face each other;
forming a first semiconductor layer on a top surface of the first bonded substrate;
forming a second semiconductor layer on a top surface of the second bonded substrate;
forming a first organic light emitting diode on the first semiconductor layer;
forming a second organic light emitting diode on the second semiconductor layer;
attaching an encapsulation substrate by an encapsulant to a surface on which each organic light emitting diode is formed;
cutting an edge portion of the first and second substrates on which the first and second semiconductor layers and the first and second organic light emitting diodes are not formed; and
separating the first and second bonded substrates into a first fabricated substrate and a second fabricated substrate.

18. The fabricating method as claimed in claim 17, wherein at least one of the first non-transmissive layer or the second non-transmissive layer is formed to have a thickness ranging from about 500 to about 3000 Å.

19. The fabricating method as claimed in claim 17, wherein at least one of the first non-transmissive layer or the second non-transmissive layer is formed by coating a UV-ray protective agent on the bottom surface of at least one of the first substrate or the second substrate.

20. The fabricating method as claimed in claim 17, wherein at least one of the first non-transmissive layer or the second non-transmissive layer is formed by forming a material selected from the group consisting of a metal that does not transmit the UV-ray, a transparent UV-ray protective agent, an opaque UV-ray protective agent, and combinations thereof on the bottom surface of at least one of the first substrate or the second substrate.

21. The fabricating method as claimed in claim 17, wherein at least one of the first non-transmissive layer or the second non-transmissive layer is formed by forming a material selected from the group consisting of chrome (Cr), chrome oxide (Cr₂O₃), aluminum (Al), gold (Au), silver (Ag), magnesium oxide (MgO), silver alloy, and combinations thereof on the bottom surface of at least one of the first substrate or the second substrate.

22. The fabricating method as claimed in claim 17, wherein the forming of at least one of the first non-transmissive layer or the second non-transmissive layer is performed by further forming a magnetic layer on a bottom surface of at least one of the first non-transmissive layer or the second non-transmissive layer.

23. The fabricating method as claimed in claim 22, wherein the forming of at least one of the first non-transmissive layer or the second non-transmissive layer is performed by further forming an anti-friction layer on a bottom surface of the magnetic layer.

24. The fabricating method as claimed in claim 17, wherein the forming of at least one of the first non-transmissive layer or the second non-transmissive layer is performed by further forming an anti-friction layer on the bottom surface of at least one of the first substrate or the second substrate.

25. The fabricating method as claimed in claim 17, wherein the encapsulation substrate used in the attaching of the encapsulation substrate has an area smaller than that of at least one of the first substrate or the second substrate.

26. The fabricating method as claimed in claim 17, wherein the cutting is performed by cutting at least one of the first substrate or the second substrate and the encapsulation substrate at a position corresponding to an outer circumference of at least one of the first semiconductor layer or the second semiconductor layer and at least one of the first organic light emitting diode or the second organic light emitting diode.

27. A moving device for an organic light emitting display comprising:
a moving body having an opening formed on one side thereof, in which a step having a depth is disposed on a circumference of the opening so as to receive the organic light emitting display formed by two bonded substrates; and
at least one shock-absorbing member extending from the step of the moving body by a distance and adapted to absorb a shock and to block the bonded organic light emitting display from warping.

28. The moving device as claimed in claim 27, further comprising an anti-slide pad disposed on the step of the moving body and adapted to receive the bonded organic light emitting display and to block the bonded organic light emitting display from sliding.

29. The moving device as claimed in claim 27, further comprising a magnet attached to a region of the shock-absorbing member facing the bonded organic light emitting display.

30. The moving device as claimed in claim 27, further comprising an elastic part disposed on a coupling region of the shock-absorbing member with the moving body.

31. A fabricating method of an organic light emitting display, the method comprising:
forming a first non-transmissive layer on a first surface of a first substrate;
forming a second non-transmissive layer on a first surface of a second substrate;
bonding the first substrate with the second substrate so that the first and second non-transmissive layers face each other;
forming a first semiconductor layer and a first organic light emitting diode on a second surface of the first bonded substrate;
forming a second semiconductor layer and a second organic light emitting diode on a second surface of the second bonded substrate;
attaching a first encapsulation substrate by an encapsulant to a surface on which the first organic light emitting diode is formed;
attaching a first encapsulation substrate by an encapsulant to a surface on which the first organic light emitting diode is formed;
cutting an edge portion of the first substrate and an edge potion of the second substrate on which the first and second semiconductor layers and the first and second organic light emitting diodes are not formed; and
separating the first and second bonded substrates into a first fabricated substrate and a second fabricated substrate.
